(19) United States
(12) Patent Application Publication
(10) Pub. No.: US 2025/0216442 A1
(43) Pub. Date: Jul. 3, 2025

(54) SOCKET ASSEMBLY AND ELECTRONIC COMPONENT TEST APPARATUS

(71) Applicant: ADVANTEST Corporation, Tokyo (JP)

(72) Inventors: Natsuki Shiota, Tokyo (JP); Yasuyuki Kato, Tokyo (JP); Jose Moreira, Boeblingen (DE)

(73) Assignee: ADVANTEST Corporation, Tokyo (JP)

(21) Appl. No.: 18/850,431

(22) PCT Filed: Mar. 24, 2022
(86) PCT No.: PCT/JP2022/014094

§ 371 Date: Sep. 24, 2024

(51) Int. Cl. G01R 31/28; G01R 1/04; G01R 29/10

(52) U.S. Cl. CPC G01R 31/2863; G01R 1/045; G01R 1/0466; G01R 29/10; G01R 31/2867; G01R 31/2874

(57) ABSTRACT

A socket assembly used in an electronic component test apparatus for testing a device under test (DUT) having a first device antenna, includes a socket in which the DUT is mounted, a pressing portion, disposed between an antenna unit and the socket, that presses the DUT toward the socket, the antenna unit having a first measuring antenna opposed to the socket, and a reinforcement frame on which the pressing portion is stacked. A material in the pressing portion has a lower dielectric constant than a material in the reinforcement frame.

### BACKGROUND

### Technical Field

The present invention relates to a socket assembly used for testing a device under test (DUT) having an antenna and an electronic component test apparatus including the socket assembly.

### Discussion of the Background

There has been known an electronic component test apparatus used for testing a DUT, which performs the test by pushing the DUT against a socket with a contact arm of an electronic component handling device (for example, Patent Document 1).

### PATENT DOCUMENT

Patent Document 1: WO2007/055004

In the above electronic component test apparatus, a holding portion of the contact arm of the electronic component handling device comes in contact with the DUT during the test of the DUT. In view of this, when a radio wave radiation characteristic test (over the air (OTA) test) is performed on a DUT having an antenna, the holding portion of the contact arm interferes with the radiation electric field of the antenna of the DUT, making it impossible to accurately measure the radio wave radiation characteristics of the antenna included in the DUT in some cases.

### SUMMARY

One or more embodiments provide a socket assembly that can improve the accuracy of a test for a DUT having an antenna and an electronic component test apparatus including the socket assembly.

A socket assembly according to one or more embodiments is used in an electronic component test apparatus for testing a DUT having a first device antenna. The socket assembly includes a socket, a pressing portion, and a reinforcement frame. The DUT is mounted in the socket. The pressing portion is disposed between an antenna unit and the socket and presses the DUT toward the socket. The antenna unit has a first measuring antenna opposed to the socket. The pressing portion is stacked on the reinforcement frame. The reinforcement frame reinforces the pressing portion. A dielectric constant of a material constituting the pressing portion is lower than a dielectric constant of a material constituting the reinforcement frame.

In one or more embodiments, the socket assembly may further include the antenna unit.

In one or more embodiments, the pressing portion may have a contact surface in contact with the DUT, the reinforcement frame may have a first opening portion, and in plan view, the first opening portion of the reinforcement frame may encompass the DUT mounted in the socket and the contact surface of the pressing portion.

In one or more embodiments, strength of the material constituting the reinforcement frame may be greater than strength of the material constituting the pressing portion.

In one or more embodiments, an area of the contact surface of the pressing portion may be greater than an area of a region where the first device antenna in the DUT is formed.

In one or more embodiments, the socket assembly may further include a device guide and a support pillar. The device guide has a second opening portion that exposes the socket, the device guide surrounding the socket. The support pillar is disposed in the device guide and supports the antenna unit.

In one or more embodiments, the socket assembly may further include an elastic member interposed between the device guide and the reinforcement frame, and the reinforcement frame may be held by the support pillar to be moveable relatively to the device guide and may be biased by the elastic member in a direction away from the device guide.

In one or more embodiments, the device guide may include a depressed portion that has the second opening portion at a bottom portion, and the depressed portion may further have a cutout portion on a wall surface that extends substantially parallel to a mounting direction of the DUT to the socket.

In one or more embodiments, the device guide may include a second measuring antenna opposed to a second device antenna disposed on a side portion of the DUT.

In one or more embodiments, the socket assembly may further include a socket cover that presses the DUT against the socket via the reinforcement frame and the pressing portion. The socket cover may include a contacting portion and a latch. The contacting portion comes in contact with the reinforcement frame. The latch engages with the device guide. The pressing portion may come in contact with the DUT mounted in the socket by bringing the contacting portion into contact with the reinforcement frame. A depressed portion engageable with the latch may be formed in the device guide, and engaging the latch with the depressed portion may allow the socket cover to be secured to the device guide.

An electronic component test apparatus according to one or more embodiments is for testing the DUT. The electronic component test apparatus includes the above-described socket assembly, a pressing device, and a tester. The pressing device presses the DUT against the socket via the reinforcement frame and the pressing portion. The tester includes a test head in which the socket assembly is mounted. The pressing device includes a contacting portion and a driving portion. The contacting portion comes in contact with the reinforcement frame. The driving portion moves the contacting portion relatively to the reinforcement frame. In a state where the DUT is electrically connected to the socket by bringing the contacting portion into contact with the reinforcement frame and pressing the DUT against the socket by the pressing portion, a radio wave is transmitted and received between the device antenna and the first measuring antenna to test the DUT.

The socket assembly according to one or more embodiments includes the pressing portion and the reinforcement frame, and the dielectric constant of the material constituting the pressing portion is lower than the dielectric constant of the material constituting the reinforcement frame. Accordingly, during an OTA test for the DUT using the socket assembly according to one or more embodiments, by pressing the reinforcement frame toward the DUT, the pressing portion constituted of the material with a low dielectric constant can be brought into close contact with the device antenna of the DUT, and interference with radiation electrolysis of the device antenna can be suppressed. Therefore, the accuracy of the test for the DUT having an antenna can be improved. In addition, in one or more embodiments, the load applied when the pressing portion is pressed against the socket is dispersed in the reinforcement frame. Therefore, even when the pressing portion is constituted of the material with a low dielectric constant, deformation or damage of the pressing portion due to the load can be suppressed.

### BRIEF DESCRIPTION OF THE DRAWINGS

FIG. 1 is a schematic cross-sectional view illustrating an overall configuration of an electronic component test apparatus according to one or more embodiments.

FIG. 2A is an enlarged view corresponding to part II of FIG. 1.

FIG. 2B is a plan view corresponding to FIG. 2A.

FIG. 3A is a drawing illustrating a state where the conveyance unit holds the DUT.

FIG. 3B is a drawing illustrating a state where the conveyance unit is conveying the DUT.

FIG. 4 is a perspective view illustrating a configuration of a socket assembly according to a first example.

FIG. 5 is a perspective view illustrating a relationship between the socket assembly and a pressing unit according to the first example, which is a drawing illustrating a state before the pressing unit presses the socket assembly.

FIG. 6 is a perspective view illustrating the relationship between the socket assembly and the pressing unit according to the first example, which is a drawing illustrating a state where the pressing unit is pressing the socket assembly.

FIG. 7 is a cross-sectional view corresponding to part VII-VII of FIG. 5.

FIG. 8 is a cross-sectional view corresponding to part VIII-VIII of FIG. 5.

FIG. 9 is a plan view corresponding to part IX-IX of FIG. 5.

FIG. 10 is a cross-sectional view corresponding to part X-X of FIG. 6.

FIG. 11 is a cross-sectional view illustrating a first modification of the socket assembly according to the first example.

FIG. 12 is a cross-sectional view illustrating a second modification of the socket assembly according to the first example.

FIG. 13 is a cross-sectional view illustrating a third modification of the socket assembly according to the first example.

FIG. 14 is a cross-sectional view illustrating a configuration of a socket assembly according to a second example, which is a drawing illustrating a state before a socket cover is mounted.

FIG. 15 is a cross-sectional view illustrating the configuration of the socket assembly according to the second example, which is a drawing illustrating a state where the socket cover is mounted.

FIG. 16 is a schematic cross-sectional view illustrating an overall configuration of a conventional electronic component test apparatus.

### DESCRIPTION OF THE EXAMPLES

The following describes embodiments based on the drawings.

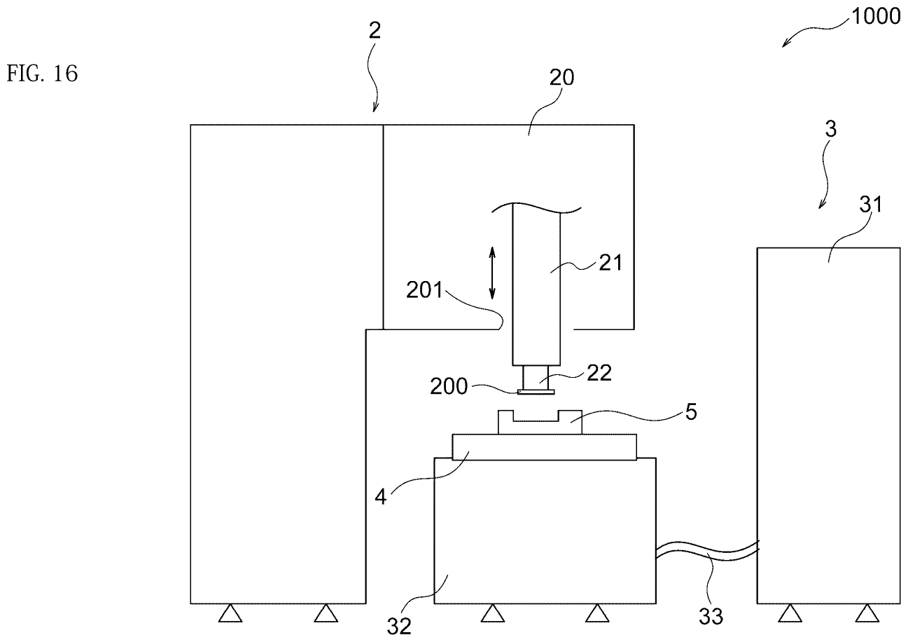

FIG. 16 is a schematic cross-sectional view illustrating an overall configuration of a

conventional electronic component test apparatus.

### First Example

A conventional electronic component test apparatus 1000 is an apparatus for testing the electrical characteristics of a DUT 200 in a state where high-or low-temperature heat stress is applied to the DUT 200 (or in a normal temperature state) and classifying the DUT 200 according to the test result. The DUT 200 as a test object is a device that does not include an antenna. Although the DUT 200 is not particularly limited, as a specific example of the DUT 200, a logic device, a system on a chip (SoC), or a memory device can be given.

The electronic component test apparatus 1000 includes, as illustrated in FIG. 16, a handler 2 that moves the DUT 200, a tester 3 that performs a test on the DUT 200, a load board 4 that is mounted on a test head 32 (described below) included in the tester 3, and a socket 5 that is mounted on the load board 4 and is electrically connectable to the DUT 200.

A tester 3 according to the example corresponds to an example of a “tester” in one or more embodiments, and a test head 32 according to the example corresponds to an example of a “test head” in one or more embodiments.

The handler 2 includes, as illustrated in FIG. 16, a constant temperature bath 20 and a contact arm 21. The handler 2 has a part projecting to a side, and the constant temperature bath 20 is housed in the projecting part. An opening 201 is formed at a bottom portion of the constant temperature bath 20, and the socket 5 is positioned inside the constant temperature bath 20 through the opening 201. Although not particularly limited, the temperature of the constant temperature bath 20 is preferably adjustable in a range of −55° C. to +155° C.

The contact arm 21 is a moving means for moving the DUT 200 and is supported by a rail (not illustrated) included in the handler 2. The contact arm 21 includes an actuator for horizontal movement (not illustrated) and can move back and forth and right and left along the rail. The contact arm 21 also includes an actuator for up-and-down driving (not illustrated) and can move up and down. The contact arm 21 includes a contact chuck 22 attached to a leading end of the contact arm 21, which allows the DUT 200 to be held and moved.

The tester 3 includes, as illustrated in FIG. 16, a main frame (tester main body) 31 and the test head 32. The main frame 31 is connected to the test head 32 via a cable 33. The main frame 31 sends a test signal to the DUT 200 through the test head 32 to test the DUT 200 and evaluates the DUT 200 according to the test result.

The test head 32 is connected to the main frame 31 via the cable 33 and sends a test signal to the DUT 200 during the test for the DUT 200. Although not particularly illustrated, a pin electronics card electrically connected to the socket 5 is housed in the test head 32.

As illustrated in FIG. 16, the load board 4 is a wiring board mounted on the test head 32 and is electrically connected to the test head 32. The socket 5 is mounted on an upper surface of the load board 4, and the test signal sent from the tester 3 is sent to the socket 5 through the load board 4. The socket 5 has a plurality of contact pins arranged to correspond to input/output terminals of the DUT 200. The DUT 200 placed on the socket 5 is pressed against the socket 5, thereby electrically connecting the socket 5 to the DUT 200.

In the conventional electronic component test apparatus 1000, the handler 2 holds the DUT 200, which has been conveyed from a customer tray by a transfer arm, by the contact chuck 22, moves the DUT 200 to the socket 5 by the contact arm 21, and presses the DUT 200 against the socket 5. Then, with the DUT 200 pressed against the socket 5, the main frame 31 of the tester 3 sends a test signal to the DUT 200 through the test head 32, the load board 4, and the socket 5 to perform a test for the electrical characteristics of the DUT 200. When the test for the DUT 200 is complete, the handler 2 holds the DUT 200 on the socket 5 by the contact chuck 22, moves the DUT 200 out of the socket 5 by the contact arm 21, and stores the DUT 200 in the customer tray by the transfer arm while classifying the DUT 200 according to the test result.

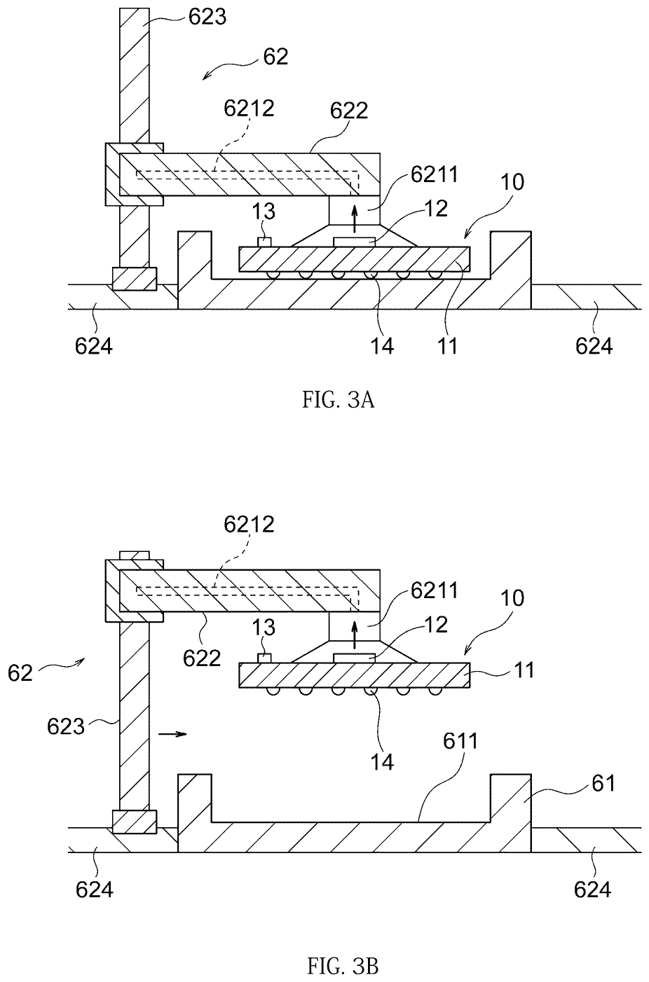

On the other hand, a DUT 10, which is a test object of an electronic component test apparatus 1 according to the example, is a so-called Antenna in Package (AiP) device and has device antennas 12 formed on a base plate 11 of the DUT 10 (see FIG. 3A). When an OTA test is to be performed on the DUT 10 using the conventional electronic component test apparatus 1000, the contact chuck 22 in contact with the DUT 10 interferes with the radiation electric field of the device antennas 12 of the DUT 10, making it impossible to accurately measure the radio wave radiation characteristics of the device antennas 12 in some cases.

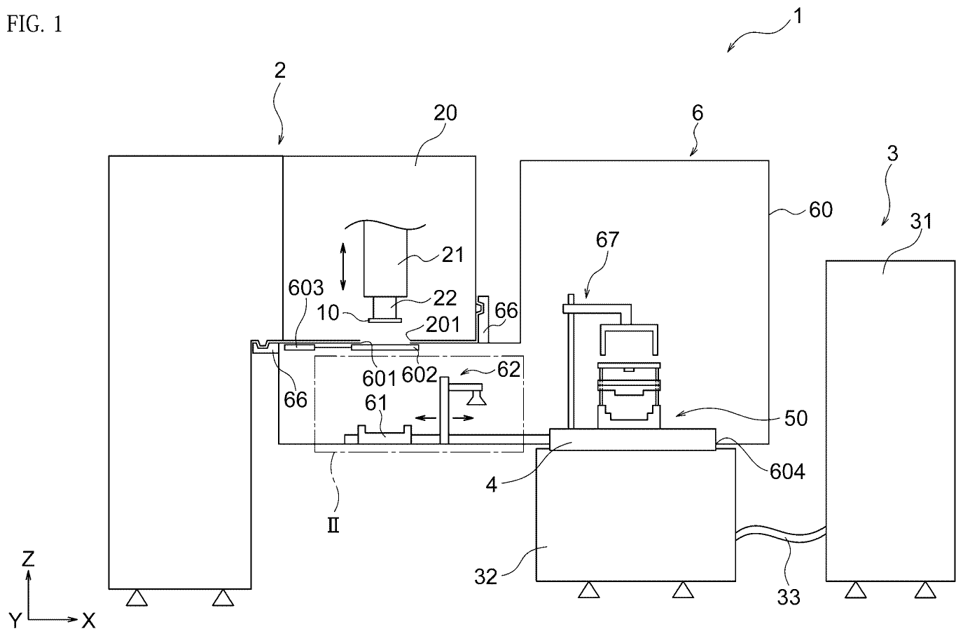

FIG. 1 is a schematic cross-sectional view illustrating an overall configuration of an electronic component test apparatus according to the example.

In contrast to this, the electronic component test apparatus 1 according to the example includes, as illustrated in FIG. 1, a socket assembly 50 including a socket 51 in which the DUT 10 is mounted in place of the socket 5 and also includes an electronic component pressing device 6 in addition to respective components included in the conventional electronic component test apparatus 1000.

The electronic component test apparatus 1 according to the example corresponds to an example of an “electronic component test apparatus” in one or more embodiments, the electronic component pressing device 6 according to the example corresponds to an example of a “pressing device” in one or more embodiments, and the socket assembly 50 according to the example corresponds to an example of a “socket assembly” in one or more embodiments.

The electronic component test apparatus 1 according to the example is an apparatus for causing a test antenna 52b (described below) to receive a radio wave at a frequency of 24.250 GHz to 52.600 GHz (a so-called millimeter wave) radiated from the DUT 10 equipped with the device antennas 12 at a near field to test the radio wave radiation characteristics of the DUT 10 and for causing the DUT 10 to receive a millimeter wave radiated from the test antenna 52b at the near field to test the radio wave reception characteristics of the DUT 10.

The DUT 10 as a test object includes the device antennas 12 formed on an upper surface of the base plate 11, a semiconductor chip 13 mounted on the upper surface of the base plate 11, and input/output terminals 14 formed on a lower surface of the base plate 11 (see FIG. 3A). The semiconductor chip 13 is a device that controls the transmission and reception by the device antennas 12. As specific examples of the device antennas 12 included in the DUT 10, patch antennas, dipole antennas, Yagi antennas, and the like can be given. Although not particularly illustrated, a semiconductor chip may be mounted on the lower surface of the base plate 11.

The DUT 10 according to the example corresponds to an example of a “DUT” in one or more embodiments, and the device antenna 12 according to the example corresponds to an example of a “first device antenna” in one or more embodiments.

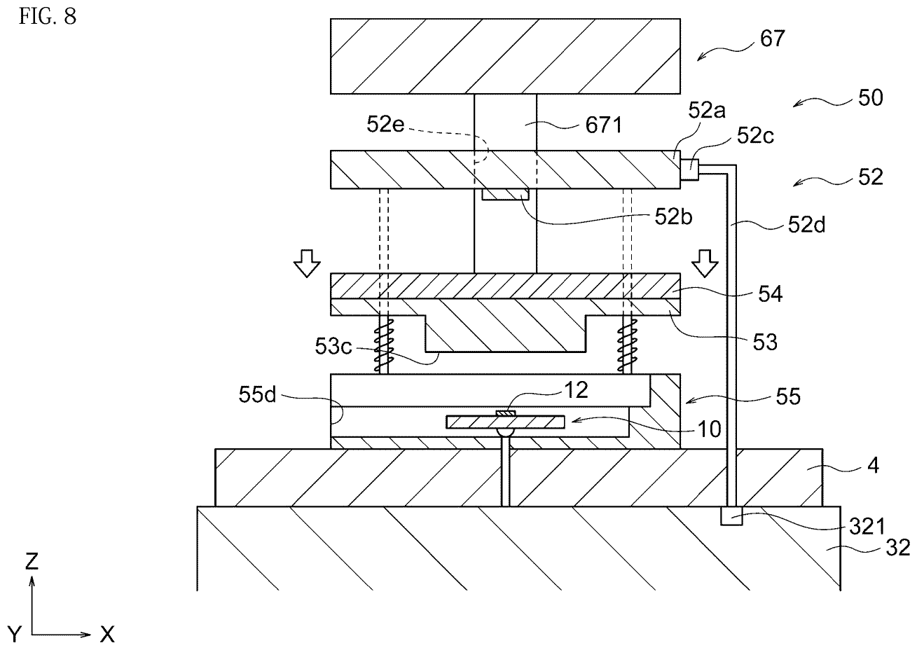

The test head 32 according to the example includes a connector 321 connectable to a coaxial connector 52c (described below) included in an antenna unit 52 (described below) (see FIG. 8). The test head 32 receives a test signal sent from the antenna unit 52 via the connector 321 and sends it to the main frame 31.

The electronic component pressing device 6 is a device that receives the DUT 10 conveyed by the contact arm 21 of the handler 2 and moves the DUT 10 to the socket 51 of the socket assembly 50 mounted on the load board 4. The electronic component pressing device 6 includes a chamber 60, a holding plate 61 on which the DUT 10 is placed, a conveyance unit 62 that moves the DUT 10 between the holding plate 61 and the socket 51, securing members 66 that secure the chamber 60 to the handler 2, and a pressing unit 67. The configuration of the pressing unit 67 will be described in detail later.

The chamber 60 is a box body connected to the constant temperature bath 20 of the handler 2 and connected to the test head 32 and houses the holding plate 61, the conveyance unit 62, and the pressing unit 67. The chamber 60 has an opening 601 formed in a position corresponding to the holding plate 61 arranged in the chamber 60, a shutter 602 configured to occlude the opening 601, an actuator 603 that operates the shutter 602, and an opening 604 connected to the load board 4.

As illustrated in FIG. 1, the chamber 60 is secured to the handler 2 by the securing members 66 in a state where the opening 601 of the chamber 60 is opposed to the opening 201 of the constant temperature bath 20. The securing member 66 includes a securing piece turnably attached to the outside of the chamber 60, and a leading end of the securing piece has a locking claw lockable on a hook disposed on a side surface of the handler 2. The electronic component pressing device 6 secures the chamber 60 to the handler 2 by locking the turning movement of the securing members 66 with the securing members 66 locked on the hooks of the handler 2. The configuration of the securing members 66 is not particularly limited to this, and for example, the chamber 60 and the handler 2 may be secured by screwing.

When the DUT 10 is tested, the shutter 602 is opened by the actuator 603, such as an electric cylinder, whereby the space in the chamber 60 communicates with the space in the constant temperature bath 20. In addition, the electronic component pressing device 6 is connected to the test head 32 through the opening 604, and the socket assembly 50 mounted on the load board 4 is positioned in the chamber 60.

The temperature in the chamber 60 is adjustable by the constant temperature bath 20 in the same temperature range as the temperature adjustment range of the constant temperature bath 20 by the space in the chamber 60 communicating with the space in the constant temperature bath 20. The chamber 60 itself may include a temperature adjustment device, and the temperature in the chamber 60 may be adjusted by the temperature adjustment device.

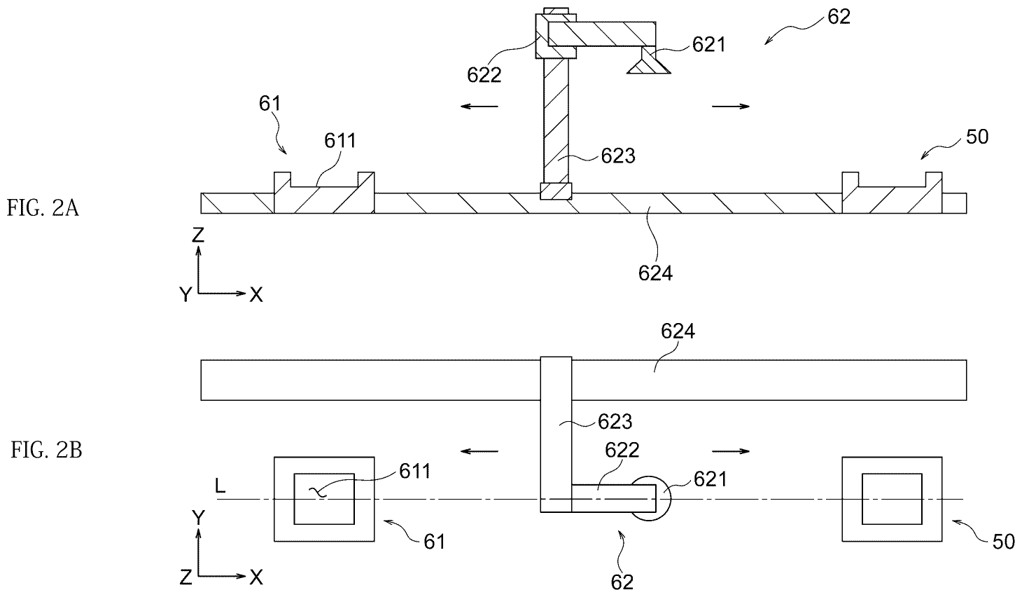

FIG. 2A is an enlarged view corresponding to part II of FIG. 1, and FIG. 2B is a plan view corresponding to FIG. 2A. FIGS. 3A and 3B are enlarged cross-sectional views illustrating the operation of a conveyance unit according to the example holding a DUT. FIG. 3A is a drawing illustrating a state where the conveyance unit holds the DUT, and FIG. 3B is a drawing illustrating a state where the conveyance unit is conveying the DUT.

The holding plate 61 is arranged, as illustrated in FIG. 1, at a position corresponding to the opening 601 of the chamber 60. As illustrated in FIGS. 2A and 2B, a depressed portion 611 is formed in the holding plate 61, allowing the DUT 10 conveyed by the contact arm 21 to be held in the depressed portion 611. Although the material of the holding plate 61 is not particularly limited, aluminum and the like can be given as an example.

The conveyance unit 62 includes, as illustrated in FIGS. 2A and 2B, a holding portion 621, a vertical moving portion 622, a horizontal moving portion 623, and a guide rail 624.

The holding portion 621 includes, as illustrated in FIGS. 3A and 3B, a suction pad 6211, a suction pipe 6212, and a vacuum pump (not illustrated). One end of the suction pipe 6212 communicates with the suction pad 6211, and the other end of a suction pipe 621b is connected to the vacuum pump. The suction pad 6211 communicates with the suction pipe 6212 and opens downward. The suction pad 6211 comes in contact with the DUT 10, thereby forming a sealed space surrounded by the suction pad 6211 and the DUT 10. Then, by sucking the air in the sealed space by the vacuum pump, the DUT 10 is sucked and held by the holding portion 621.

As illustrated in FIG. 2B, the holding portion 621 is attached to the vertical moving portion 622 so as to be positioned on a virtual straight line L connecting the holding plate 61 to the socket assembly 50 in plan view. The holding portion 621 can be moved in a horizontal direction along the guide rail 624 by the horizontal moving portion 623 and positioned directly above each of the holding plate 61 and the socket 51 of the socket assembly 50.

The vertical moving portion 622 is connected to an actuator not particularly illustrated, allowing the holding portion 621 to be moved up and down as illustrated in FIGS. 3A and 3B.

The horizontal moving portion 623 is connected to an actuator not particularly illustrated, allowing the holding portion 621 to be moved in the horizontal direction as illustrated in FIGS. 2A and 2B.

As illustrated in FIG. 2B, the guide rail 624 is arranged substantially parallel to the virtual straight line L connecting the holding plate 61 to the socket assembly 50. As illustrated in FIGS. 2A and 2B, the length of the guide rail 624 is set longer than at least the distance between the holding plate 61 and the socket assembly 50.

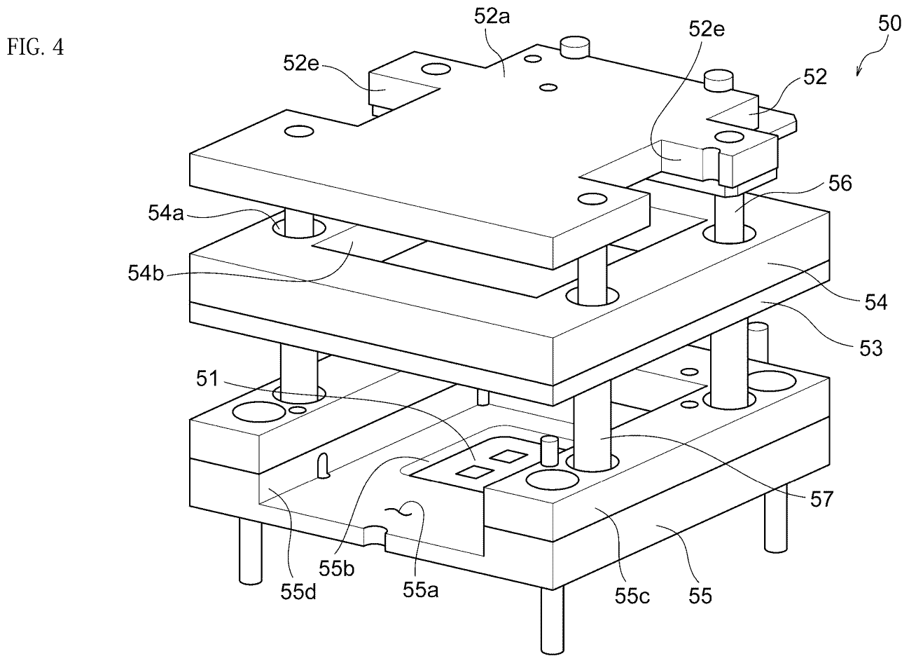

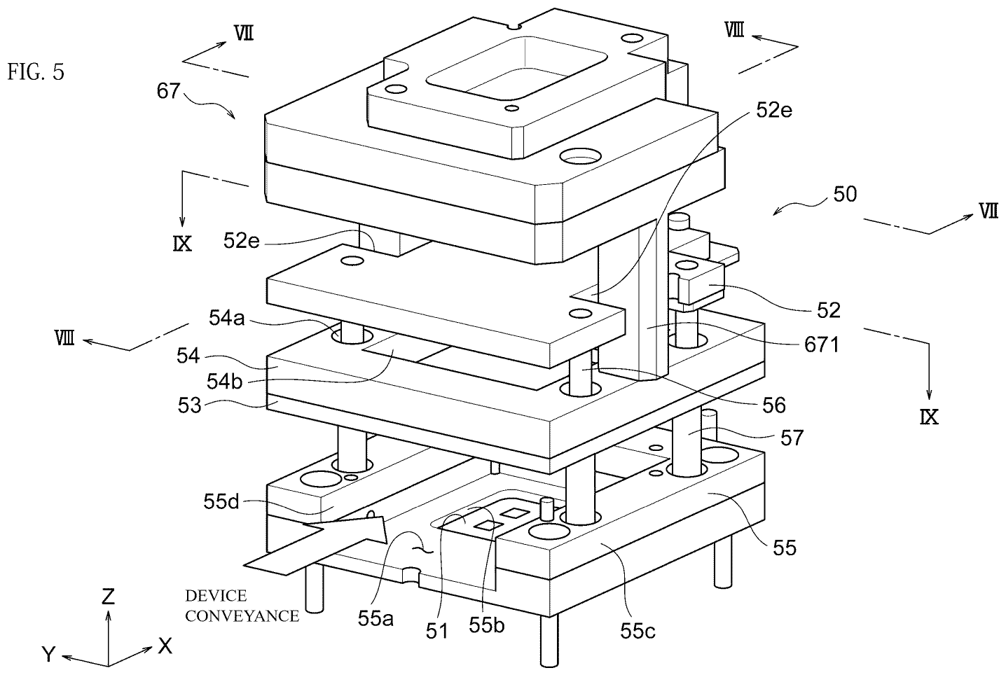

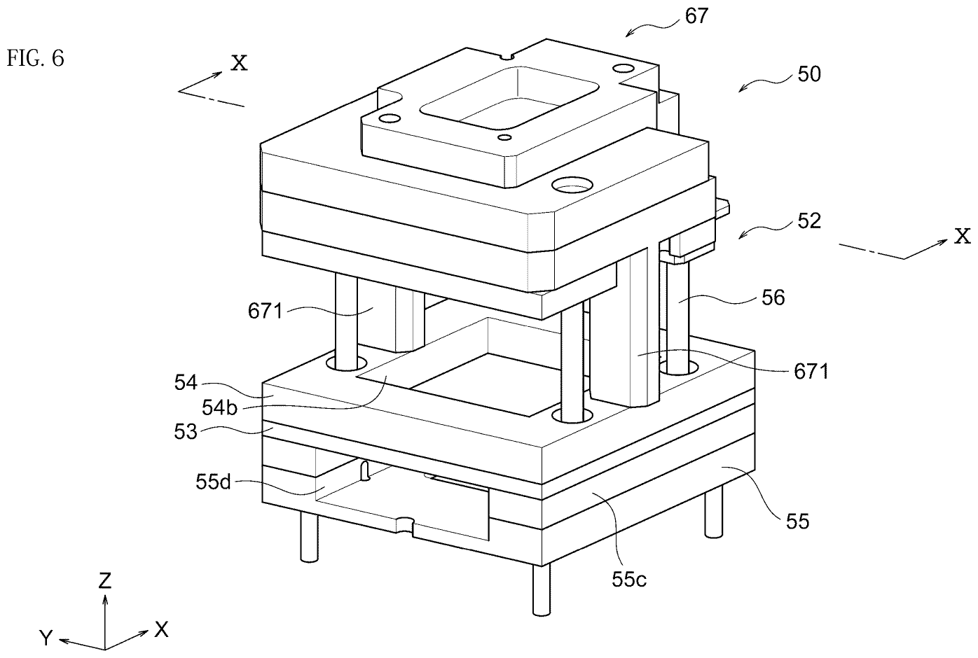

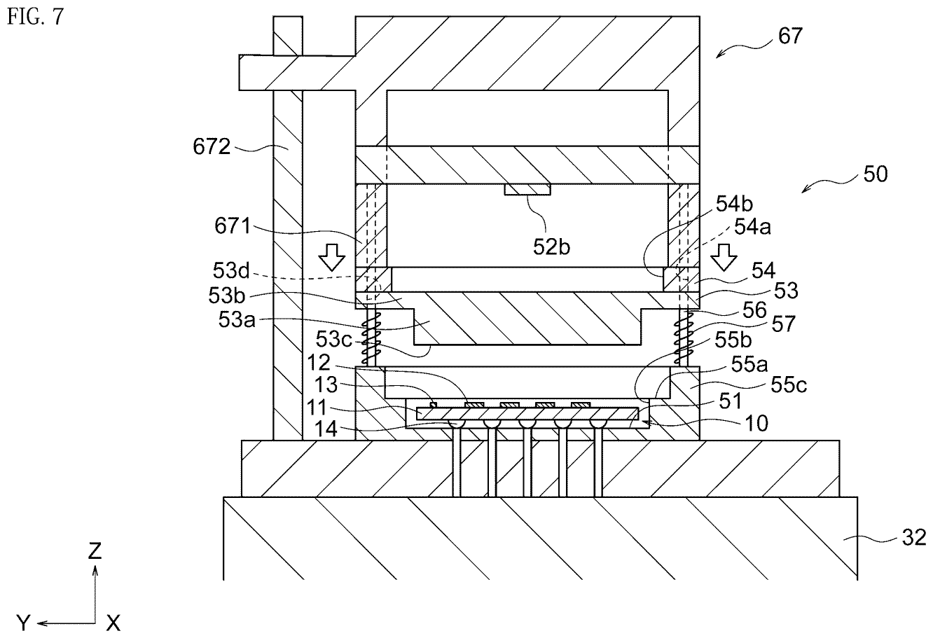

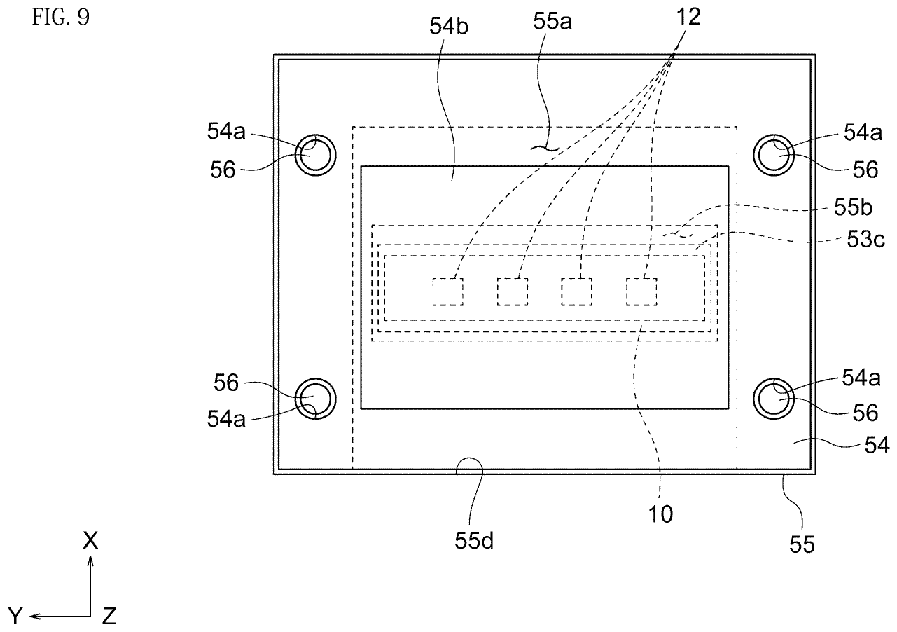

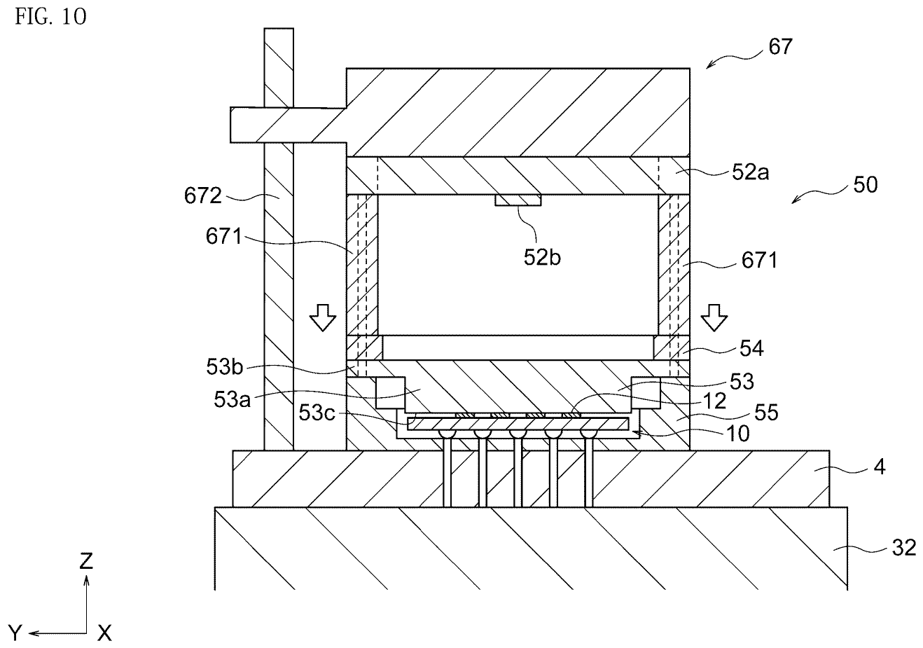

FIG. 4 is a perspective view illustrating a configuration of a socket assembly according to the example. FIG. 5 and FIG. 6 are perspective views illustrating a relationship between the socket assembly and a pressing unit according to the example. FIG. 5 is a drawing illustrating a state before the pressing unit presses the socket assembly, and FIG. 6 is a drawing illustrating a state where the conveyance unit is conveying the DUT. FIG. 7 is a cross-sectional view corresponding to part VII-VII of FIG. 5. FIG. 8 is a cross-sectional view corresponding to part VIII-VIII of FIG. 5. FIG. 9 is a plan view corresponding to part IX-IX of FIG. 5. FIG. 10 is a cross-sectional view corresponding to part X-X of FIG. 6.

The socket assembly 50 includes, as illustrated in FIG. 4, the socket 51 in which the DUT 10 is mounted, the antenna unit 52, a pusher 53 that presses the DUT 10, a frame 54 that reinforces the pusher 53, a device guide 55 that surrounds the socket 51, support pillars 56, and springs 57. The socket assembly 50 is used for the OTA test for the DUT 10 and is exchangeable corresponding to the variety of the DUT 10.

The device guide 55 is a member disposed on the load board 4 to surround the socket 51 and is secured to the load board 4 by screwing or the like. A depressed portion 55a depressed in a downward direction (Z-axis negative direction) in the drawing is formed in the device guide 55, and an opening portion 55b that exposes the socket 51 in an upward direction (Z-axis positive direction) is formed at a bottom portion of the depressed portion 55a. The device guide 55 is constituted of a high-strength resin material, such as a PEEK material. Although the strength is not particularly limited, as a specific example of the strength according to the example, compressive strength can be given. The device guide 55 may be constituted of a plurality of members, and for example, the device guide 55 may have a two-layer structure. Furthermore, the plurality of members may be configured by different materials.

In the device guide 55, a wall portion 55c arranged to surround the depressed portion 55a is disposed. In the wall portion 55c, a cutout portion 55d is formed. The cutout portion 55d is formed at a part in the wall portion 55c, which intersects with a conveying direction of the DUT 10 into the socket assembly 50. That is, as illustrated in FIG. 9, the wall portion 55c of the device guide 55 has an approximately U-shaped shape in plan view.

Back to FIG. 4, in the wall portion 55c of the device guide 55, the four support pillars 56 are disposed in the upward direction in the drawing. The support pillars 56 pass through the pusher 53 and the frame 54 to be connected to a base plate 52a (described below) of the antenna unit 52 and support the antenna unit 52. The number of the support pillars 56 is not particularly limited to this and may be less than four or equal to or more than five. The distance between the device guide 55 and the base plate 52a of the antenna unit 52 is fixed by the support pillars 56, and consequently, the distance between the socket 51 and the test antenna 52b (described below) of the antenna unit 52 is fixed.

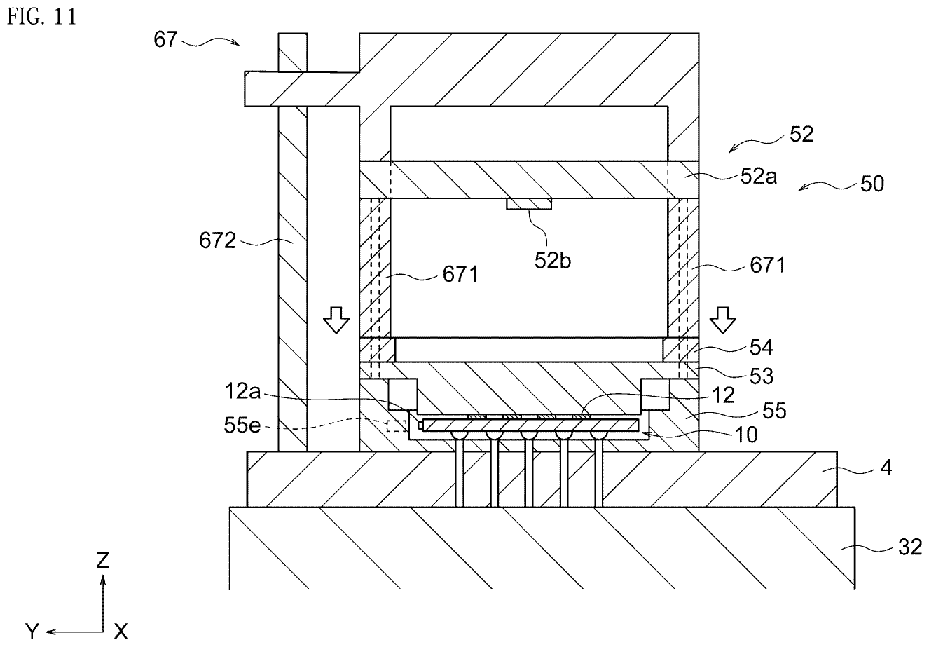

FIG. 11 is a cross-sectional view illustrating a first modification of the socket assembly according to the example.

As illustrated in FIG. 11, the DUT 10 may include a device antenna 12a disposed at a side portion of the DUT 10 in addition to the device antennas 12. In this case, the device guide 55 further includes a test antenna 55e. The test antenna 55e is arranged at a position opposed to the device antenna 12a of the DUT 10 mounted in the socket 51.

As illustrated in FIG. 8, the antenna unit 52 includes the base plate 52a, the test antenna 52b, the coaxial connector 52c, and a communication line 52d.

The base plate 52a is connected to and supported by the support pillars 56. As illustrated in FIG. 4, two cutouts 52e are formed in the base plate 52a. Then, as illustrated in FIG. 5, through the cutouts 52e, contacting portions 671 of the pressing unit 67 described below can come in contact with the frame 54.

As illustrated in FIG. 8, the test antenna 52b is disposed on a lower surface of the base plate 52a and at a position opposed to the DUT 10 mounted in the socket 51. The test antenna 52b is an antenna that receives a radio wave radiated from the device antennas 12 of the DUT 10 and radiates a radio wave to the device antennas 12 of the DUT 10. By placing the DUT 10 in the socket 51, the test antenna 52b is opposed to the device antennas 12 of the DUT 10.

The distance between the test antenna 52b and the device antennas 12 of the DUT 10 is fixed by the support pillars 56 described above to adjust the radio wave radiated from the device antennas 12 to be able to reach a test antenna 641 at the near field. Although the test antenna 52b is not particularly limited, for example, a patch antenna (microstrip antenna), a horn antenna, and the like can be given as examples.

In the example, the radio wave radiated from the device antennas 12 is adjusted to reach the test antenna 52b at the near field, but is not particularly limited to this. The radio wave radiated from the device antennas 12 may be adjusted to reach the test antenna 52b at a far field.

The coaxial connector 52c is attached to the base plate 52a and is electrically connected to the test antenna 52b via a wiring pattern (not illustrated) formed on the lower surface of the base plate 52a.

The communication line 52d has one end connected to the coaxial connector 52c and the other end connected to the connector 321 of the test head 32. A communication line 643B has a function that mutually transmits electrical signals between a test antenna 641B and the connector 321.

As a method of connecting the test antenna 52b to the tester 3, a waveguide may be used for the connection. When a waveguide is used, a waveguide including a back-short structure is connected to the base plate 52a. Then, by connecting the other end of the waveguide to a waveguide coaxial conversion connector disposed in the test head 32, the test antenna 52b is connected to the tester 3.

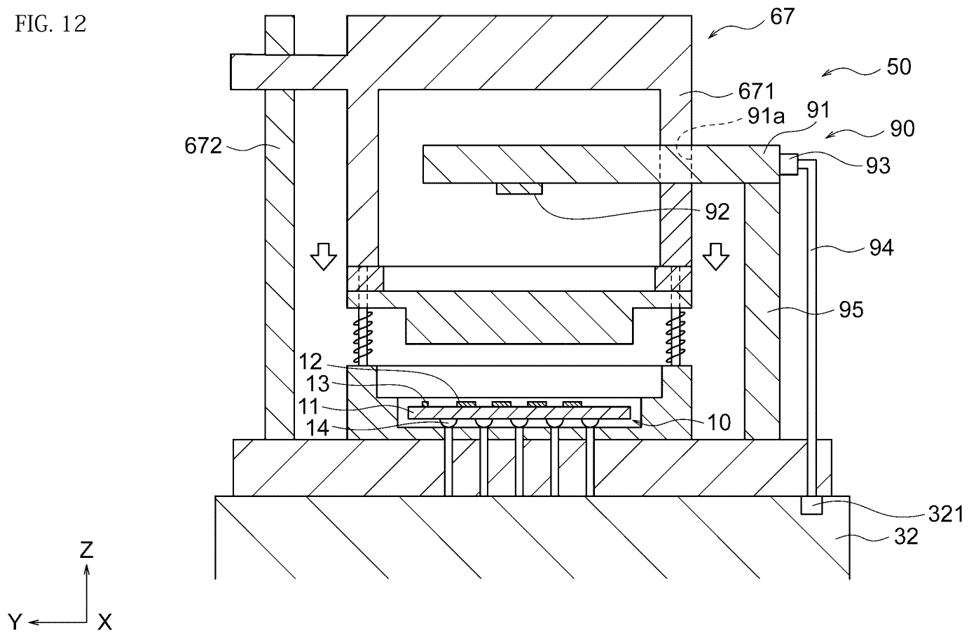

FIG. 12 is a cross-sectional view illustrating a second modification of the socket assembly according to the example.

In the example, the antenna unit 52 is incorporated into the socket assembly 50, but is not particularly limited to this. For example, as illustrated in FIG. 12, an antenna unit 90 independent of the socket assembly 50 may be supported separately from the socket assembly 50 by a support body 95 disposed in the chamber 60 on the load board 4 or around the opening 604 of the chamber 60. Similarly to the antenna unit 52, the antenna unit 90 includes a base plate 91, a test antenna 92, a coaxial connector 93, and a communication line 94. A through hole 91a, through which the contacting portion 671 of the pressing unit 67 is insertable, is formed in the base plate 91 of the antenna unit 90.

Back to FIG. 4, the frame 54 is a rectangular frame body disposed between the base plate 52a of the antenna unit 52 and the socket 51. In the frame 54, four through holes 54a are formed, and the support pillars 56 pass through the through holes 54a. The frame 54 is biased in a direction away from the device guide 55 by the springs 57 disposed between the device guide 55 and the frame 54 and is held to be moveable relatively to the device guide 55. The frame 54 is constituted of a high-strength resin material, such as a PEEK material. The strength of the material constituting the frame 54 is greater than the strength of the material constituting the pusher 53.

As illustrated in FIG. 9, a rectangular opening portion 54b is formed in a central portion of the frame 54 in plan view. The opening portion 54b has a size large enough to encompass the DUT 10 mounted in the socket 51 in plan view. In addition, the opening portion 54b has a size large enough to encompass a contact surface 53c of the pusher 53 described below in plan view.

The pusher 53 includes, as illustrated in FIG. 7, a contact portion 53a and a holding portion 53b. The holding portion 53b is attached to the frame 54 to cover the opening portion 54b of the frame 54. In a part in the holding portion 53b, which overlaps with the wall portion 55c of the device guide 55 and the frame 54, through holes 53d through which the support pillars 56 pass are formed. The contact portion 53a has a shape projecting from the holding portion 53b toward the socket 51. A lower surface of a contact portion 53ab is the contact surface 53c with the DUT 10 and is substantially parallel to a surface on which the device antennas 12 of the DUT 10 are formed. The pusher 53 is secured to the frame 54 with an adhesive or the like. The pusher 53 is constituted of a material with a lower dielectric constant than that of the material constituting the frame 54. As the material, for example, a hard foam made of a resin material or the like can be given as an example. The dielectric constant can be controlled by adjusting a foaming rate.

The pusher 53 can be moved downward as the pressing unit 67 described below pushes the frame 54 downward. As illustrated in FIG. 10, the pusher 53 moves down, thereby allowing the contact surface 53c of the pusher 53 to be brought into close contact with the device antennas 12 of the DUT 10 mounted in the socket 51.

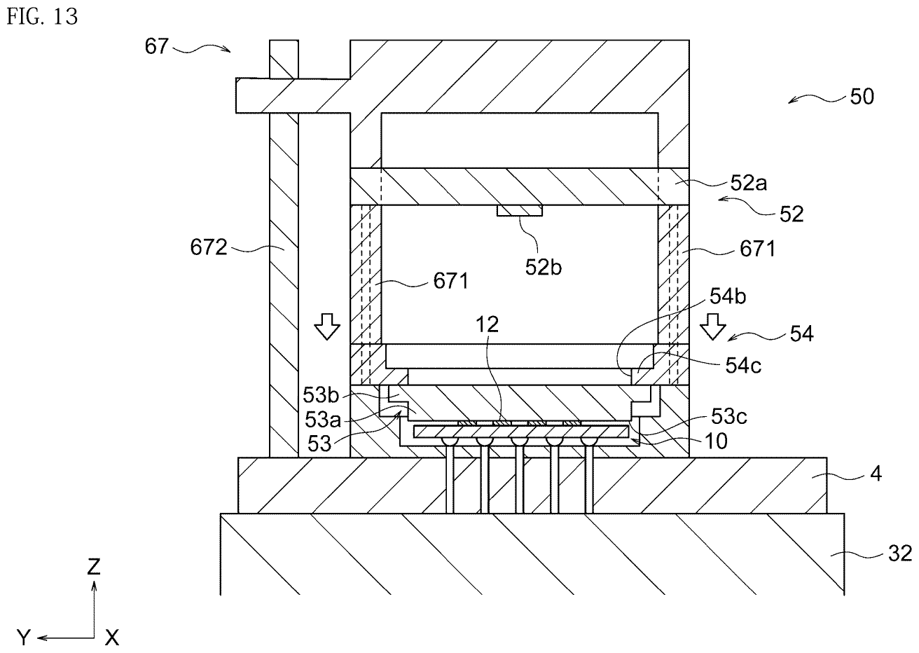

FIG. 13 is a cross-sectional view illustrating a third modification of the socket assembly according to the example.

While the pusher 53 is configured such that the holding portion 53b comes in contact with the wall portion 55c of the device guide 55, the configuration of the pusher 53 is not particularly limited to this. For example, as illustrated in FIG. 13, the frame 54 may include a projecting portion 54c that projects toward an inner side with respect to the wall portion 55c of the device guide 55, and the holding portion 53b of the pusher 53 may be secured to the projecting portion 54c of a frame 5. That is, the pusher 53 may be configured to be arranged on the inner side of the wall portion 55c of the device guide 55. In this form, when the frame 54 is pushed downward by the pressing unit 67, the pusher 53 does not come in contact with the wall portion 55c of the device guide 55. Accordingly, deformation of the pusher 53 can be suppressed, and the pusher 53 can come in contact with the device antennas 12 of the DUT 10 more uniformly.

As illustrated in FIG. 7, the pressing unit 67 of the electronic component pressing device 6 includes the contacting portions 671 that press the frame 54 of the socket assembly 50 downward and a driving portion 672 that automatically moves the contacting portions 671 up and down. As illustrated in FIG. 5, the contacting portions 671 have a shape projecting downward corresponding to the cutouts 52e formed in the base plate 52a of the antenna unit 52 and can come in contact with the frame 54 through the cutouts 52e. By pushing the contacting portions 671 downward by the driving portion 672 in a state where the contacting portions 671 are in contact with the frame 54, the DUT 10 can be pressed against the socket 51 via the frame 54 and the pusher 53 as illustrated in FIG. 6. Although not particularly limited, the driving portion 672 is constituted of an electric cylinder or the like and is secured to the chamber 60 around the opening 604 of the chamber 60.

The following describes the OTA test for the DUT 10 with the electronic component test apparatus 1 according to the example.

First, in a state where the opening 201 of the constant temperature bath 20 of the handler 2 is opposed to the opening 601 of the chamber 60 of the electronic component pressing device 6, the chamber 60 is secured to the handler 2 by the securing members 66, and the electronic component pressing device 6 is connected to the handler 2. In addition, the test head 32 is connected to the electronic component pressing device 6 by putting the socket assembly 50 into the chamber 60 through the opening 604.

Next, the constant temperature bath 20 is started to adjust the temperature in the constant temperature bath 20 and the temperature in the chamber 60 to a predetermined temperature. When the chamber 60 itself includes a temperature adjustment device, the temperature in the chamber 60 may be adjusted by the temperature adjustment device in place of the constant temperature bath 20.

Next, the DUT 10 is held by the contact chuck 22 of the handler 2, and the DUT 10 is placed on the holding plate 61.

Next, the conveyance unit 62 sucks and holds the DUT 10 to move the DUT 10 from the holding plate, and as illustrated in FIG. 5, the DUT 10 is put into the inside of the socket assembly 50 through the cutout portion 55d of the device guide 55 of the socket assembly 50 to mount the DUT 10 in the socket 51.

Next, as illustrated in FIG. 7, the contacting portions 671 are moved down by the driving portion 672 of the pressing unit 67 from a state where the frame 54 is biased in the upward direction by the springs 57. Accordingly, the frame 54 in contact with the contacting portions 671 moves down as illustrated in FIG. 10, and the contact surface 53c of the pusher 53 attached to the frame 54 is brought into close contact with the four device antennas 12 of the DUT 10. In this state, the following radio wave radiation characteristics test and radio wave reception characteristics test are performed on the DUT 10.

Specifically, a test signal output from the main frame 31 is first sent to the DUT 10 via the load board 4 mounted on the test head 32 and the socket 51. The DUT 10 that receives this test signal radiates a radio wave upward from the device antennas 12. The radio wave passes through the pusher 53, is received by the test antenna 52b, and is converted into an electric signal, which is sent to the main frame 31 via the coaxial connector 52c, the communication line 52d, the connector 321, and the test head 32. Based on the signal, the radio wave radiation characteristics of the DUT 10 are evaluated.

Next, in a state where the DUT 10 is still pressed against the socket 51, a test signal output from the main frame 31 is sent to the test antenna 52b via the communication line 52d and the coaxial connector 52c. The test antenna 52b that receives this test signal radiates a radio wave downward. The radio wave passes through the pusher 53, is received by the device antennas 12 of the DUT 10, and is converted into an electric signal, which is sent to the main frame 31 via the socket 51 and the load board 4. Based on the signal, the radio wave reception characteristics of the DUT 10 are evaluated.

After the DUT 10 is evaluated, the contacting portions 671 are moved up by the driving portion 672, and the DUT 10 is moved from the socket 51 to the holding plate 61 by the conveyance unit 62. Furthermore, the DUT 10 is moved from the holding plate 61 by the contact arm 21 of the handler 2. The DUT 10 moved into the handler 2 is stored in the customer tray while being classified according to the test results by the transfer arm and taken out from the handler 2 to a post-process. This concludes the tests for the DUT 10.

As described above, in the example, the socket assembly 50 includes the pusher 53 and the frame 54, and the dielectric constant of the material constituting the pusher 53 is lower than the dielectric constant of the material constituting the frame 54. This does not cause the pusher 53 to interfere with the radiation electric field of the device antennas 12 of the DUT 10 even when the pusher 53 comes in contact with the device antennas 12 during the test for the DUT 10. Therefore, the accuracy of the test for the DUT 10 can be improved.

Additionally, in the example, the pusher 53 is attached to the frame 54 constituted of a high-strength material. If the socket assembly does not include a frame, and the pressing unit directly presses the pusher, the applied load may deform or damage the pusher. In contrast to this, in the example, since the load applied by the pressing unit 67 is dispersed throughout the frame 54, the deformation and damage of the pusher 53 can be suppressed, and the contact surface 53c of the pusher 53 can be brought into contact with the device antennas 12 of the DUT 10 uniformly.

Furthermore, in the example, the antenna unit 52 and the pusher 53 are incorporated into the socket assembly 50, and components having structures depending on the variety of the DUT 10 are aggregated into the socket assembly 50. In view of this, when the variety of the DUT 10 as a test object is exchanged, it is possible to perform a test on a different variety of DUT 10 simply by exchanging the socket assembly 50 attached to the load board 4 for a socket assembly 50 corresponding to the other variety of DUT 10. Thus, by using the socket assembly 50 according to the example, the variety of the DUT 10 is easily exchanged.

### Second Example

In the example, a manual electronic component test apparatus is described. In the electronic component test apparatus, the DUT 10 is manually mounted in a socket assembly 50B without using the handler 2 or the electronic component pressing device 6. While the socket assembly 50B according to the example differs from the first example in that a socket cover 58 is further included, the configuration other than that is similar. The following only describes the difference of the socket assembly 50B according to the second example from the first example. The same reference numerals are attached to parts having a similar configuration to the first example, and their descriptions are omitted.

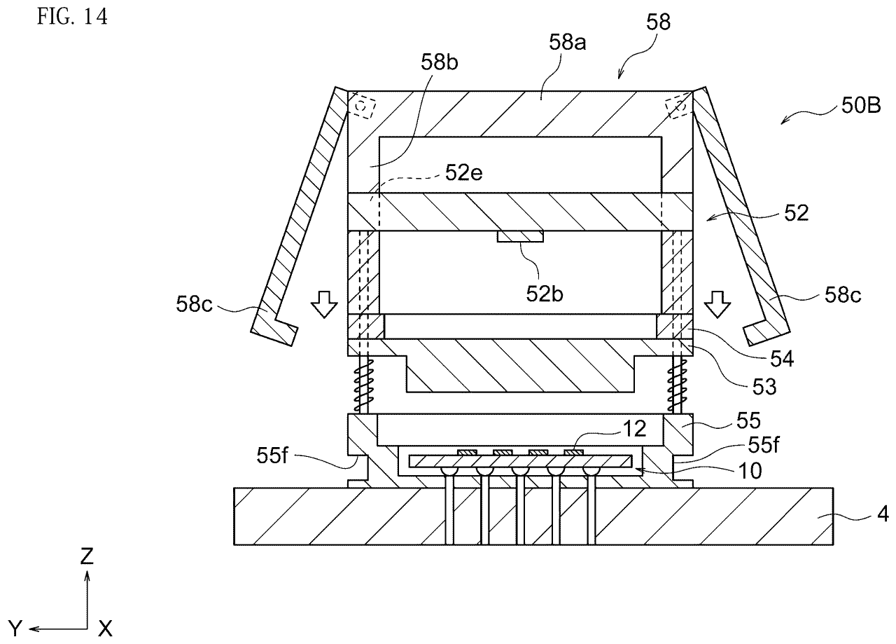

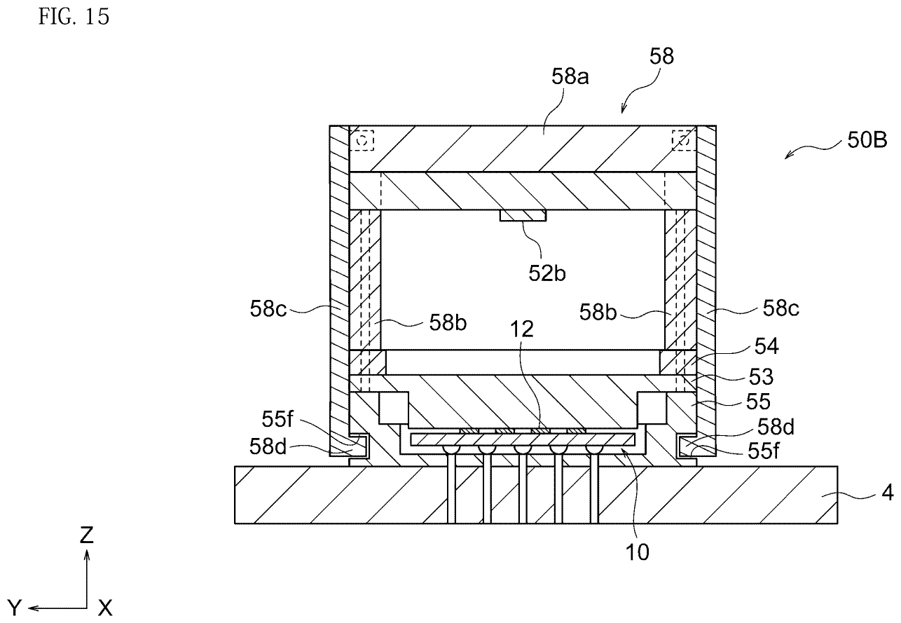

FIG. 14 and FIG. 15 are cross-sectional views illustrating a configuration of a socket assembly according to the example. FIG. 14 is a drawing illustrating a state before a socket cover is mounted, and FIG. 15 is a drawing illustrating a state where the socket cover is mounted.

The socket assembly 50B according to the example further includes, as illustrated in FIG. 14, the socket cover 58 in addition to the socket 51, the antenna unit 52, the pusher 53, the frame 54, the device guide 55, the support pillars 56, and the springs 57.

The socket cover 58 includes a main body portion 58a, contacting portions 58b, and latches 58c. The contacting portions 58b have a shape projecting downward from the main body portion 58a and can come in contact with the frame 54 through the cutouts 52e formed in the base plate 52a of the antenna unit 52.

The latch 58c has one end rotatably supported by the main body portion 58a. An engaging portion 58d that engages with a depressed portion 55f formed in the device guide 55 is formed at the other end of the latch 58c.

In the socket assembly 50B according to the example, as illustrated in FIG. 15, the pusher 53 can be brought into contact with the device antennas 12 of a DUT 100 by pushing the socket cover 58 downward with the DUT 10 mounted in the socket 51 and bringing the contacting portions 58b into contact with the frame 54 to press the frame 54. Furthermore, by engaging the engaging portions 58d of the latches 58c with the depressed portions 55f of the device guide 55 with the pusher 53 brought into contact with the DUT 100, the socket cover 58 is secured to the device guide 55, and a state where the DUT 100 is pressed against the socket 51 is maintained to be able to perform a test on the DUT 10.

The OTA test for the DUT 10 by an electronic component test apparatus 1B according to the example is described. The process until the DUT 10 is placed on the socket 51 is the same as that of the OTA test in the first example. As illustrated in FIG. 15, in the example, in a state where the socket cover 58 is secured to the device guide 55 and the pusher 53 attached to the frame 54 in contact with the contacting portions 58b presses the DUT 10 against the socket 51 as illustrated in FIG. 15, the radio wave radiation characteristics test and the radio wave reception characteristics test are performed on the DUT 10.

Also in the electronic component test apparatus 1B according to the example, the socket assembly 50B includes the pusher 53 and the frame 54, and the dielectric constant of the material constituting the pusher 53 is lower than the dielectric constant of the material constituting the frame 54. This does not cause the pusher 53 to interfere with the radiation electric field of the device antennas 12 of the DUT 10 even when the pusher 53 comes in contact with the device antennas 12 during the test for the DUT 10. Therefore, the accuracy of the test for the DUT 10 can be improved.

The examples described above are described for ease of understanding of the embodiments and are not described for the purpose of limiting the present invention. Therefore, each element disclosed in the above embodiments is intended to include all design changes and equivalents within the technical scope of the present invention. Although the disclosure has been described with respect to only a limited number of embodiments, those skilled in the art, having benefit of this disclosure, will appreciate that various other embodiments may be devised without departing from the scope of the present invention. Accordingly, the scope of the invention should be limited only by the attached claims.

For example, the electronic component test apparatus 1 described above includes the electronic component pressing device 6, but is not particularly limited to this. The electronic component test apparatus 1 need not include the electronic component pressing device 6, and the DUT 10 may be mounted in the socket 51 with a moving device, such as a robot arm. In this case, the moving device described above corresponds to an example of the “pressing device” in one or more embodiments.

### DESCRIPTION OF REFERENCE NUMERALS

1, 1B, 1000 Electronic component test apparatus
2 Handler
21 Contact arm
22 Contact chuck
3 Tester
31 Main frame
32 Test head
321 Connector
33 Cable
4 Load board
50, 50B Socket assembly
51 Socket
52 Antenna unit
52a Base plate
52b Test antenna
52c Coaxial connector
52d Communication line
52e Cutout
53 Pusher
53a Contact portion
53b Holding portion
53c Contact surface
54 Frame
54a Through hole
54b Opening portion
54c Projecting portion
55 Device guide
55a Depressed portion
55b Opening portion
55c Wall portion
55d Cutout
55e Test antenna
56 Support pillar
57 Spring
58 Socket cover
58 Main body portion
58b Contacting portion
58c Latch
58d Engaging portion
6 Electronic component conveying device
60 Chamber
601 Opening
602 Shutter
604 Opening
61 Holding plate
611 Depressed portion
62 Conveyance unit
67 Electronic component pressing unit
671 Contacting portion
672 Driving portion
10, 200 DUT

1. A socket assembly used in an electronic component test apparatus for testing a device under test (DUT) having a first device antenna, the socket assembly comprising:
a socket in which the DUT is mounted;
a pressing portion, disposed between an antenna unit and the socket, that presses the DUT toward the socket, the antenna unit having a first measuring antenna opposed to the socket; and
a reinforcement frame on which the pressing portion is stacked, wherein
a material in the pressing portion has a lower dielectric constant than a material in the reinforcement frame.

2. The socket assembly according to claim 1, further comprising the antenna unit.

3. The socket assembly according to claim 1, wherein
the pressing portion has a contact surface that contacts the DUT, and
the reinforcement frame has a first opening portion that in plan view, encompasses the DUT mounted in the socket and the contact surface of the pressing portion.

4. The socket assembly according to claim 1, wherein the material in the reinforcement frame has greater strength than the material in the pressing portion.

5. The socket assembly according to claim 3, wherein the contact surface of the pressing portion has a larger area than a region where the first device antenna is disposed in the DUT.

6. The socket assembly according to claim 2, further comprising:
a device guide, having a second opening portion that exposes the socket, surrounding the socket; and
a support pillar disposed in the device guide and supporting the antenna unit.

7. The socket assembly according to claim 6, further comprising:
an elastic member disposed between the device guide and the reinforcement frame, wherein
the reinforcement frame, held by the support pillar that moves relative to the device guide, is biased by the elastic member in a direction away from the device guide.

8. The socket assembly according to claim 6, wherein the device guide includes a depressed portion having:
the second opening portion at a bottom portion of the device guide; and
a cutout portion on a wall surface of the device guide extending substantially parallel to a mounting direction of the DUT to the socket.

9. The socket assembly according to claim 6, wherein the device guide includes a second measuring antenna opposed to a second device antenna disposed on a side portion of the DUT.

10. The socket assembly according to claim 6, further comprising:
a socket cover that presses the DUT against the socket via the reinforcement frame and the pressing portion, wherein
the socket cover includes:
a contacting portion that contacts the reinforcement frame; and
a latch that engages the device guide,
the pressing portion contacts the DUT mounted in the socket by the contacting portion contacting the reinforcement frame,
the device guide has a depressed portion, and
the latch engages the depressed portion such that the socket cover is to the device guide.

11. An electronic component test apparatus for testing the DUT, the electronic component test apparatus comprising:
the socket assembly according to claim 1;
a pressing device that presses the DUT against the socket via the reinforcement frame and the pressing portion; and
a tester including a test head in which the socket assembly is mounted, wherein
the pressing device includes:
a contacting portion that contacts the reinforcement frame; and
a driving portion that moves the contacting portion relatively to the reinforcement frame, and
when the DUT is electrically connected to the socket by the contacting portion contacting the reinforcement frame and by the pressing portion pressing the DUT against the socket, a radio wave is transmitted and received between the device antenna and the first measuring antenna to test the DUT.
